(19) United States
(12) Patent Application Publication
(10) Pub. No.: US 2023/0175126 A1
(43) Pub. Date: Jun. 8, 2023

(54) REACTANT VAPOR DELIVERY SYSTEMS FOR SEMICONDUCTOR PROCESSING TOOLS AND METHODS

(71) Applicant: ASM IP Holding B.V., Almere (NL)

(72) Inventors: Jianqiu Huang, Phoenix, AZ (US); Gnyanesh Trivedi, Tempe, AZ (US); Thomas Fitzgerald, Gilbert, AZ (US); Akshay Phadnis, Phoenix, AZ (US); Yingzong Bu, Powell, OH (US); Paul Ma, Scottsdale, AZ (US); Shubham Garg, Tempe, AZ (US)

(21) Appl. No.: 18/072,773

(22) Filed: Dec. 1, 2022

Related U.S. Application Data
(60) Provisional application No. 63/264,978, filed on Dec. 6, 2021.

(51) Int. Cl. C23C 16/44; C23C 16/458; C23C 16/455

(52) U.S. Cl. CPC C23C 16/4405; C23C 16/4583; C23C 16/45565; C23C 16/45578; H01L 21/68757

(57) ABSTRACT

A reactor can include a reaction chamber, a substrate support configured to support a substrate on a top side of the substrate support, and an elongate delivery apparatus disposed within the reaction chamber. The substrate support may be actuated to an upper position and to a lower position along a vertical axis within the reaction chamber. The substrate support may have a maximum horizontal dimension from the vertical axis along a horizontal axis substantially orthogonal to the vertical axis. The elongate delivery apparatus may have an inner horizontal dimension greater than the maximum horizontal dimension of the substrate support. The delivery apparatus can allow gas to pass through an interior of the delivery apparatus. The delivery apparatus can include a plurality of apertures. Each of the plurality of apertures can allow passage of the gas from the interior of the delivery apparatus into the reaction chamber.

### CROSS-REFERENCE TO RELATED APPLICATIONS

This application is a nonprovisional of, and claims priority to and the benefit of, U.S. Provisional Patent Application No. 63/264,978, filed Dec. 6, 2021 and entitled “REACTANT VAPOR DELIVERY SYSTEMS FOR SEMICONDUCTOR PROCESSING TOOLS AND METHODS,” which is hereby incorporated by reference herein.

### BACKGROUND

### Field of the Disclosure

This disclosure relates generally to semiconductor processing, tools therefor, and more particularly to reactant vapor delivery systems and methods.

### Description of the Related Art

Semiconductor fabrication processes are typically conducted with the substrates supported within a reaction chamber on a substrate support under controlled process conditions. For many processes, reactant vapors are delivered from above the semiconductor substrates (e.g., wafers) within the reaction chamber. The delivery of the reactant vapors to the substrates for various purposes can be improved.

### SUMMARY

In some embodiments, a reactor includes a flange disposed between an upper chamber and a lower chamber. The reactor also includes a substrate support that is configured to support a substrate on a top side of the substrate support. The substrate support can be configured to be vertically actuated between an upper position and a lower position within the reaction chamber. The reactor includes a primary gas delivery apparatus that is disposed within the upper chamber and is configured to deliver gas to an upper surface of the substrate. The reactor can include an elongate gas delivery apparatus that is disposed within the lower chamber and is configured to partially surround the substrate support. The delivery apparatus can be configured to allow gas to pass through an interior thereof and out a plurality of apertures in fluid communication with the interior of the delivery apparatus.

In some embodiments, a reactor includes a reaction chamber and a substrate support at a horizontal position within the reaction chamber. The substrate support can be configured to support a substrate on a top side of the substrate support. The substrate support can be configured to be vertically actuated between an upper position and a lower position within the reaction chamber. The reactor can include an elongate gas delivery apparatus disposed within the reaction chamber to partially surround the substrate support horizontal position. The gas delivery apparatus can have an inner horizontal width greater than a horizontal width of the substrate support. The delivery apparatus can be configured to allow gas to pass through an interior thereof. The delivery apparatus can include a plurality of apertures in fluid communication with the interior of the delivery apparatus. Each of the plurality of apertures can be configured to allow passage of the gas from the interior of the delivery apparatus into the reaction chamber. The plurality of apertures can be disposed below the top of the substrate support when the substrate support is in the upper position and level with or above an edge of the substrate support when the substrate support is in the lower position.

In some embodiments, a delivery apparatus for delivering gas within a reaction chamber includes an elongate tube that is configured to be disposed within the reaction chamber. The tube can be configured to allow gas to pass through an interior thereof. The tube can include an arched segment partially surrounding a horizontal position of a substrate support within the chamber. The reactor can include an inlet adapter that is configured to couple to a base of the reaction chamber and feed reaction vapors therethrough to the tube. The reactor may further include a plurality of apertures that are in fluid communication with the interior of the tube. Each of the plurality of apertures can be configured to allow passage of the gas from the interior of the delivery apparatus into the reaction chamber.

In some embodiments, a method for delivering cleaning gas within a reactor includes positioning a substrate on a substrate support within an upper chamber of a reactor. The method includes delivering reactant vapor to the substrate via a showerhead delivery apparatus within the upper chamber and removing the substrate from the reactor. The method includes positioning the substrate support at a horizontal position within a lower chamber of the reactor and delivering cleaning gas through an interior of a gas delivery apparatus positioned within the lower chamber via a plurality of apertures of the gas delivery apparatus.

In some embodiments, a method for delivering reactant vapor within a reactor includes loading a substrate onto a substrate support within a reactor and positioning the substrate support within a lower chamber of the reactor. The method further includes delivering reactant gas through an interior of an elongate delivery apparatus positioned within the lower chamber.

In some embodiments, a method for delivering chamber gas within a reaction chamber includes actuating a substrate support between a processing position for processing a substrate and a lower position along a vertical axis within the reaction chamber. In the lower position, a top of the substrate support is level with or below an arcuate delivery apparatus. The arcuate delivery apparatus can have an inner width greater than an outer width of the substrate support. The method may include while in the lower position, passing gas through an interior of the arcuate delivery apparatus and into the reaction chamber via a plurality of apertures of the arcuate delivery apparatus.

### BRIEF DESCRIPTION OF THE DRAWINGS

FIG. 1 shows an example reactant vapor delivery system that includes a reactor and a substrate support in a lower position.

FIG. 2 shows a perspective view of an example reactant vapor delivery system in relation to a substrate support.

FIG. 3 shows a top view of the example reactant vapor delivery system and substrate support of FIG. 2.

FIG. 4 shows a side view of the example reactant delivery system and substrate support of FIG. 2.

FIG. 5 shows an example flow pattern for the reactant vapor delivery system of FIG. 2.

FIG. 6A is a perspective view of a delivery apparatus adapter.

FIG. 6B is a cross-sectional side view of the delivery apparatus adapter of FIG. 6A.

FIG. 6C shows the delivery apparatus adapter of FIG. 6A coupled to an inlet of the delivery apparatus and to a base of a reaction chamber.

FIG. 7 shows an example method that may be performed using the illustrated reactant gas delivery system for chamber cleaning gas.

FIG. 8 shows an example method that may be performed using the illustrated reactant gas delivery system for processing a substrate.

### DETAILED DESCRIPTION

Although certain embodiments and examples are disclosed below, it will be understood by those having ordinary skill in the art that the invention extends beyond the specifically disclosed embodiments and/or uses of the invention and obvious modifications and equivalents thereof. Thus, it is intended that the scope of the invention herein disclosed should not be limited by the particular disclosed embodiments described below.

Semiconductor substrate preparation and processing can require precision manufacturing techniques and apparatus. Moreover, processing equipment can require maintenance and cleaning. Described herein are various embodiments for improving the cleanliness and quality of substrate processing.

Various reaction processes can occur within a reaction chamber of a reactor. These reaction processes can include deposition processes, such as chemical vapor deposition (CVD) and atomic layer deposition (ALD), among other processes. During certain reactions, reactant vapors are passed over the heated substrate, causing the chemical vapor deposition (CVD) of a thin layer of a desired material on the substrate. Through sequential processing, multiple layers are made into integrated circuits. Other exemplary processes include sputter deposition, masking steps, dry etching, plasma processing (including plasma assisted deposition and etching processes), and high temperature annealing, etc. Many of these processes employ high temperatures, such that means are typically provided for heating the substrate on the substrate support, such as radiant heating, convective heating, resistive heating, etc. Regardless of whether externally or internally heated, the substrate support is often referred to in the industry as a heater or a susceptor.

The diameter of the substrate can influence the processing as well. In recent years, single-substrate processing of large diameter substrates has become more widely used for a variety of reasons, including the desire for greater precision in process control than may be achieved with batch-processing. Substrates may be made of silicon and may have a diameter of about 150 mm (about 6 inches) or of about 200 mm (about 8 inches) and have a thickness of about 0.725 mm. Recently, larger silicon substrates with a diameter of about 300 mm (about 12 inches) and a thickness of about 0.775 mm have been utilized because they exploit the benefits of single-substrate processing even more efficiently. Even larger substrates are expected in the future. A typical single-substrate substrate support includes a pocket or recess within which the substrate rests during processing. In many cases, the recess is shaped to receive the substrate very closely.

A substrate may be moved within the reaction chamber by an effector or other robotic substrate handling device, such as a fork, paddle, electrostatic wand, vacuum wand or Bernoulli wand. A Bernoulli wand is described in U.S. Pat. No. 5,997,588, the entire disclosure of which is hereby incorporated by reference herein for all purposes. Depending upon the end effector type, the substrate support may or may not include lift pins.

During reaction operation, vapors including reactant vapors and/or inert gases (e.g., carrier and/or purge gas) may flow into the reaction chamber through one or more reaction chamber inlets, and vapors such as excess reactants, reactant byproducts, and inert gases may flow out of the reaction chamber through one or more reaction chamber outlets. Inert gases can include a single inert gas or a mixture of inert gases and may include one or more noble gases (e.g., helium, argon, neon, xenon, etc.). A delivery system such as a showerhead assembly may generally deliver the vapors near an upper surface of the substrate. The delivery system can cause gas to flow generally perpendicularly to a face of the substrate. “Gas” or “vapor” may be used interchangeably herein, regardless of whether the substance is naturally gaseous or is vaporized for delivery. An example of a showerhead implemented within a reaction chamber is described in U.S. Pat. No. 10,872,804, the entire disclosure of which is hereby incorporated by reference herein for all purposes.

The reaction chamber can include one or more gas delivery mechanisms for delivering reactant vapors into the reaction chamber. The gas delivery apparatus can be disposed at a horizontal position within the reactor such that it can deliver vapors to a top side of the substrate support when the support is in a lower position, and that the delivery apparatus can deliver reactant vapors to an underside of the support. Because the substrate support of the illustrated embodiment is configured only for vertical movement, the horizontal position can be the same in the upper chamber and the lower chamber of the reaction chamber. The flexibility afforded by relative movement of the support with respect to the reactant vapor delivery mechanism can help ensure reactant vapors, such as equipment cleaning vapors, reach all desired equipment surfaces.

The delivered reactant vapor may be a process reactant vapor for processing the substrate, an etchant gas, or some other gas. For example, an etchant gas such as NF₃ may be used to clean one or more equipment surfaces within the reaction chamber, typically in the absence of a substrate. Cleaning interior parts of a reaction chamber can be time-consuming and require significant downtime for the reaction chamber as a person accesses the part(s) within the reaction chamber that need to be cleaned. The reactant vapor delivery systems described herein can improve the thermal cleaning process in a variety of ways. For example, the improved reactant vapor delivery systems can clean the chamber in situ and thus minimize downtime and maximize periods between disassembling the reactor for more thorough ex situ cleaning. Additionally or alternatively, the vapor delivery systems described herein can minimize particle contamination from flaking or spalling of undesired deposition on equipment surfaces by facilitating more frequent cleaning cycles.

By allowing cleaning gas to be delivered within the chamber, the cleaning can be more targeted. For example, the cleaning gas may be released below the substrate support (e.g., in a lower chamber of the reaction chamber) when the substrate support is in an upper position. This can allow the reactant vapor delivery system to clean an underside of the substrate support and/or other elements within the reaction chamber that are difficult to access without ex situ cleaning.

Additionally or alternatively, the substrate support may be moved to a lower position where the gas can be delivered to targeted portions of the support and/or other areas close by. For example, the reactant vapor delivery system can deliver gas to edges of the support to clean the substrate support edges from previous reaction processes (e.g., deposition processes). Additionally or alternatively, sides or edges of the substrate support may be cleaned to improve a seal between the substrate support and a flange of the reaction chamber when the substrate support is in the upper, processing position. For example, the substrate support may form a seal with a flange of the reaction chamber when the substrate support is in the upper position, in some embodiments, defining an upper chamber. In some embodiments there may be no seal and a gap may be present between the reaction chamber flange and the substrate support in the processing position.

As discussed above, the reactant vapor may include an etchant or other cleaning gas for treating reaction chamber surfaces. However, the reaction vapor delivery system may additionally or alternatively be configured to deliver processing reaction vapors for processing a substrate. For example, the reaction vapor delivery apparatus may serve as a secondary injector to deliver reaction vapors to supplement processing reaction vapors from a primary reaction vapor delivery system (e.g., a showerhead), or to provide a subset of reactants to interact with the reactants from the primary injector. Thus, such a delivery apparatus can supplement and/or replace a showerhead, in some implementations. In some embodiments, it may be advantageous to have processing vapors delivered from both a showerhead and a cross-flow injector such as the partial ring of the illustrated embodiments.

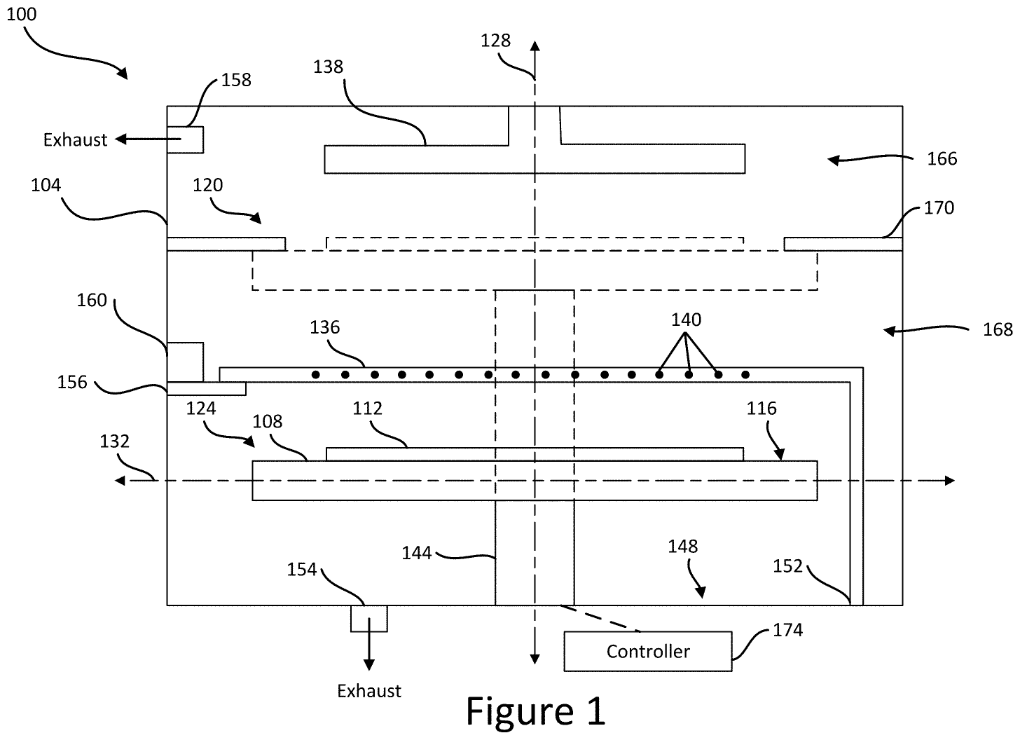

Reference will now be made to the Figures. FIG. 1 shows an example reactor 100 that includes a reaction chamber 104 and a substrate support 108 in a lower position 124. The reaction chamber 104 may include an upper chamber 166 and a lower chamber 168 separated by a flange 170. The substrate support 108 can support a substrate 112 (e.g., wafer) thereon. The reactor 100 can further include a gas delivery apparatus 136 disposed within the reaction chamber 104 (e.g., within the lower chamber 168). In the illustrated embodiment, the reactor 100 further includes a showerhead 138 disposed above the substrate support 108 that is configured to deliver gas generally downward parallel to a vertical axis toward a top of the substrate 112. In the illustrated embodiment, the showerhead 138 can serve as a primary reaction vapor delivery apparatus, or injector, where the term “primary” is merely a label and does not imply relative importance. The upper chamber 166 can include an upper chamber outlet 158 that is configured to draw vapors out of the upper chamber 166 (e.g., during processing). In some embodiments, the upper chamber outlet 158 may work in conjunction with the lower chamber outlet 154 to draw vapors out of the reaction chamber 104 as desired to tune gas flow paths through the chamber 104.

In some embodiments, the reactor 100 can include a viewport 160 that can allow visual inspection of the substrate support 108 and/or the substrate 112, for example to ensure substrate 112 seating during processing, or to inspect a level of accumulated residue on the equipment. The reactor 100 can additionally or alternatively include one or more apparatus supports 156 that support the gas delivery apparatus 136. The one or more apparatus supports 156 may be coupled (e.g., attached to) the viewport 160.

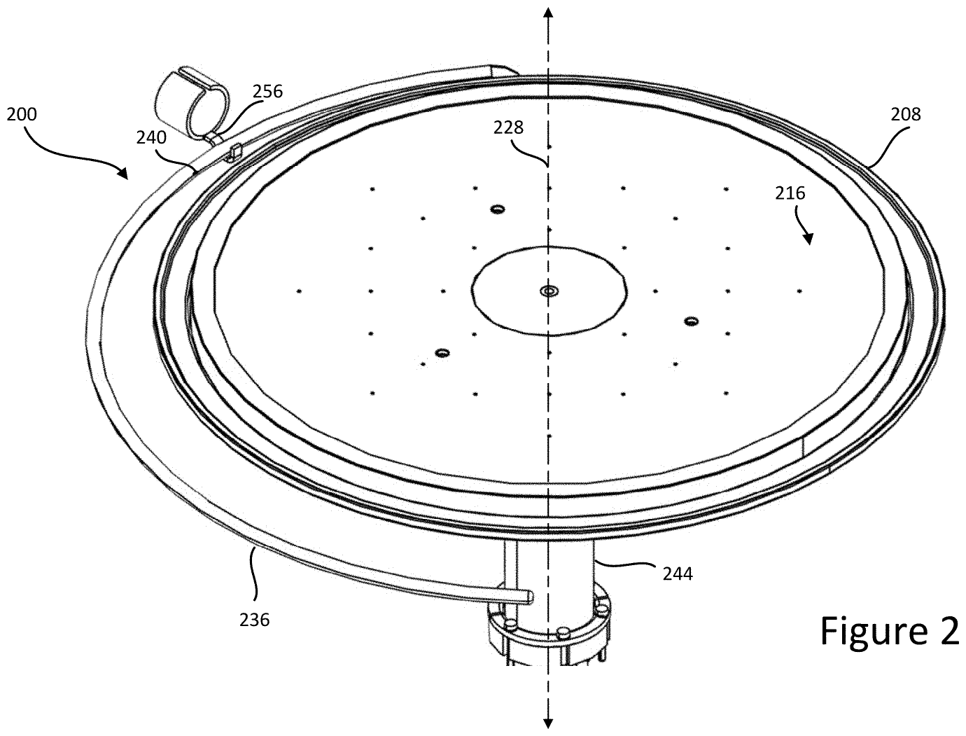

The gas delivery apparatus 136 can include an elongate tube that is configured to be disposed within the reaction chamber 104. The tube can include one or more apertures 140, illustrated as horizontally oriented. The tube can be generally disposed along a horizontal plane, generally parallel to the top side 116 of the substrate support 108. Additionally or alternatively, the one or more apertures 140 can be vertically oriented, or at other orientations between vertical and horizontal. The one or more apertures 140 can be configured to allow passage of gas from the interior of the gas delivery apparatus 136 into the reaction chamber 104. As will be appreciated from FIGS. 2-5, the tube of the gas delivery apparatus 136 can be shaped to at least partially surround the substrate support 108 in a horizontal plane and have an inner dimension that is greater than a maximum width of a substrate support 108 within the reaction chamber. For example, in the illustrated embodiment, the tube is curved and forms an arc or partial ring that has an inner radius greater than an outer radius of the substrate support 108. The radial dimension of the substrate support 108 and the tube of the gas delivery apparatus 136 may be measured along a horizontal axis 132, which is substantially perpendicular to the vertical axis 128. The tube is hollow such that it allows reactant vapors to pass through an interior thereof. The interior of the tube may be in fluid communication with the one or more apertures 140. The skilled artisan will appreciate that, while there are advantages to the illustrated round shape of the tube, for example allowing an even distance from the apertures 140 to the edge of the substrate support 108, the tube can have other shapes, such as ovular or rectangular.

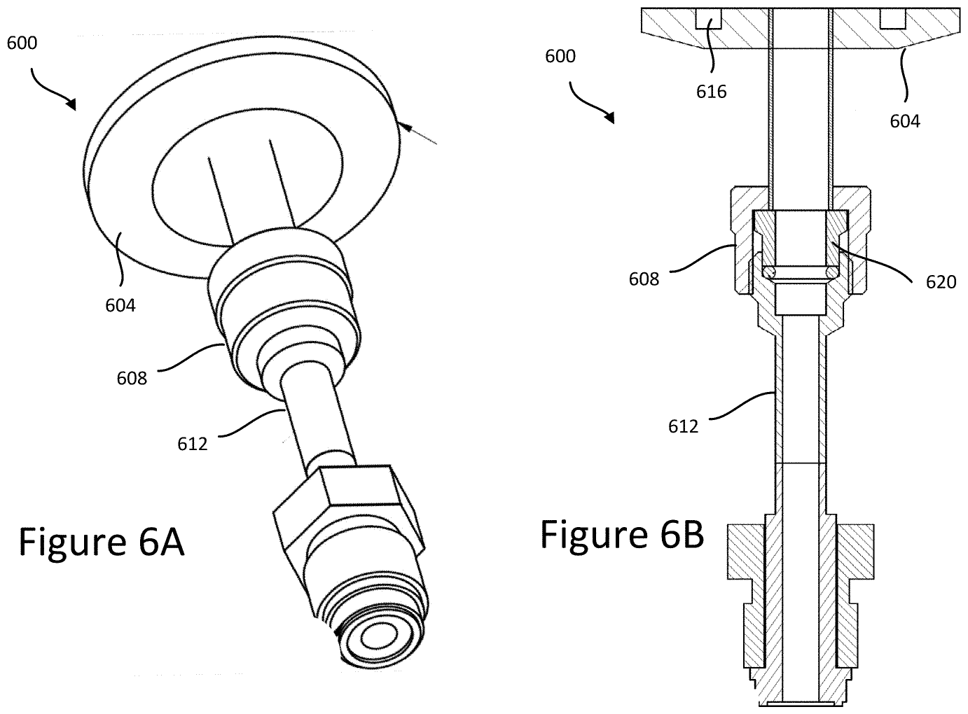

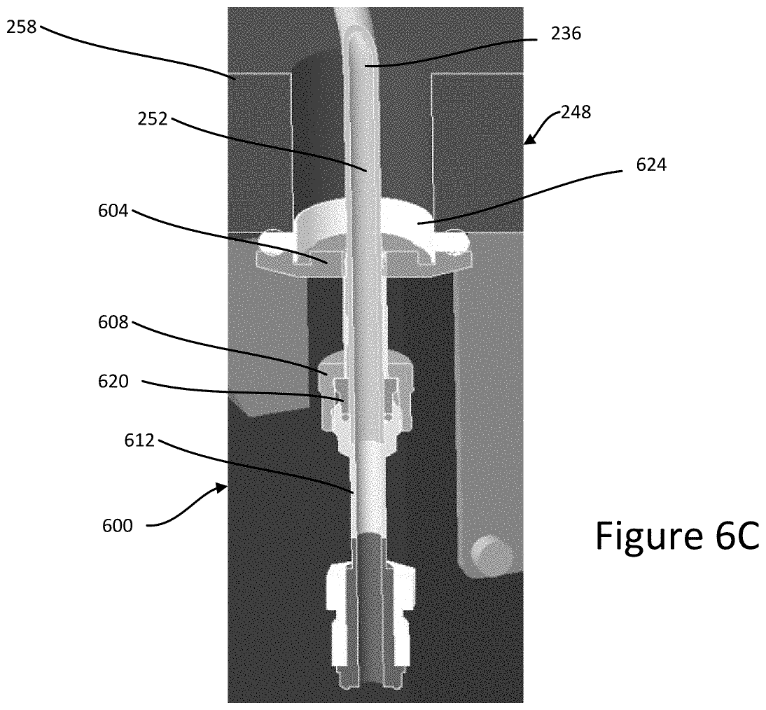

The gas delivery apparatus 136 can include an inlet 152 that is configured to couple to a chamber base 148 of the reaction chamber 104. The inlet 152 can include a delivery apparatus adapter (see, for example, FIGS. 6A-6B and attendant description) that couples to the chamber base 148 of the reaction chamber 104. Gas can pass from a gas source (e.g., a gas bomb or a vaporizer outside the reaction chamber 104) through the inlet 152 into the gas delivery apparatus 136.

The reaction chamber 104 can include a lower chamber outlet 154, such as in the chamber base 148. The lower chamber outlet 154 can be configured to draw the gas out of the chamber. For example, a vacuum pump may be coupled to the lower chamber outlet 154 and/or to the upper chamber outlet 158. In some embodiments, each of the lower chamber outlet 154 and upper chamber outlet 158 are coupled to separate vacuum pumps that can be operated independently by a controller 174. The lower chamber outlet 154 may be configured to operate only during a cleaning procedure in some embodiments.

As noted above, and with reference to FIGS. 2-5, the tube of the gas delivery apparatus 136 can form at least a portion of an arc, arched segment, or partial ring, in a horizontal plane, or more generally in a plane parallel with the substrate support 108. The portion of the arc can encompass an obtuse angle. In some embodiments, the angle may be greater than 180° and may be about 200°, about 220°, about 240°, about 260°, about 280°, about 300°, about 320°, about 340°, about 360°, any angle therein or fall within a range having endpoints therein. In some embodiments the angle is about 120°. Each of the one or more apertures 140 may be disposed along the portion of the arc, such as along an inner radius of the portion of the arc. For example, each of the one or more apertures are configured to inject vapors along a horizontal plane. In operation, each of the one or more apertures can direct the gas toward the chamber outlet 154, which is positioned in the illustrated embodiment at the lower wall or base 148 of the reaction chamber 104 such that the reaction vapors traverse the horizontal position of the substrate support 108 between the apertures 140 and the chamber outlet 154 when the support 108 is in a lower, or cleaning, position. This location may help direct the reaction vapors through the reaction chamber 104 in a manner that ensures the reaction vapors reach surfaces of the lower chamber (below the flange 170), particularly for embodiments in which the reaction vapors comprise cleaning gas, regardless of whether the cleaning gas is released above or below the substrate support 108.

The substrate support 108 can include an outer edge forming an outer perimeter around a face or top of the substrate support 108. The substrate support 108 may comprise one or more materials, such as elemental or molecular materials. Such materials can include non-oxide ceramics, such as silicon carbide (SiC), graphite, or any other ceramic.

Other materials may be used, such as metal. In some embodiments, the substrate support 108 may include a silicon carbide coating, such as silicon-carbide-coated graphite. In some embodiments, the substrate support 108 can have a raised ledge around the perimeter to define a pocket sized and shaped to accommodate a particular type of substrate, such as a 200-mm wafer or a 300-mm wafer.

The substrate support 108 may be configured to be raised and lowered by a motor attached to a shaft 144 along a vertical axis 128. The shaft 144 can raise the substrate support 108 to various vertical positions in the chamber, including an upper position 120, which can serve as a processing position with a substrate 112 supported, and the lower position 124, which in some embodiments described herein can serve as a load/unload position and/or a cleaning position. When in the upper position 120, the substrate support 108 may contact a flange 170, thereby substantially creating a fluid barrier between the upper chamber 166 and the lower chamber 168, thus allowing for processing of the substrate 112 within the upper chamber 166. The flange 170 may include a ring, such as a metal ring. In other embodiments, the substrate support 108 may form a small gap with the flange 170 in the upper position, with controlled minimal flow therethrough, or a labyrinth seal may be formed between the substrate support 108 and the flange 170.

The reactor 100 can include the controller 174 that includes one or more processors, as well as a memory with executable instructions thereon. When executed by the processor, the one or more processors can implement processes related to delivery of reactant vapors, raising, lowering and rotation of the shaft 144 by way of motors, modifying a temperature of one or more heating elements within the reactor 100, controlling a flow of vapors through various valves, substrate movement through robotics, etc. The skilled artisan will appreciate that the controller 174 can be programmed to implement the processes described herein. For example, the processor can process recipes through control of robotics, temperature controllers, valves and other flow control equipment, gate valves, substrate support positioning and rotation motors, etc. A recipe may be, for example, an ordering and/or length of times of reaction processes for specific reactant vapors. The reactor 100 also includes reaction vapor sources, such as gas bombs or vaporizing tools, connected to the showerhead 138 and the inlet 152.

In the upper position 120, a top side 116 or face of the substrate support 108 and/or a top side of the substrate 112 may be above the apertures 140 disposed within the gas delivery apparatus 136. Additionally or alternatively, in the lower position 124, the top side 116 of the substrate support 108 and/or the top side of the substrate 112 may be below the apertures 140. In some embodiments, the apertures 140 may be approximately level with the substrate support 108 in the lower position 124. Thus, the gas delivery apparatus 136 can be disposed such that it can deliver gas to different portions of the substrate support 108 and/or the substrate 112, depending on the position of the substrate support 108 relative to the gas delivery apparatus 136.

As noted above, the face or top of the substrate support 108 may be shaped to accommodate specific substrates, such as 200-mm or 300-mm wafers. Additionally or alternatively, the substrate support 108 may have a relatively low profile (i.e., general cross-sectional thickness) to reduce weight of the substrate support 108 and/or to allow for more precise handling of the substrate. The top side 116 of the substrate support 108 may be substantially round, to form an approximately circular substrate support 108.

The substrate support 108 may include one or more apertures configured to allow raisers (e.g., lift pins, prongs, rods, etc.) therethrough. The raisers may be used to receive the substrate 112 on the substrate support 108 on loading and to separate the substrate 112 from the substrate support 108 on unloading. The top side 116 may have a sloped and/or concave outer surface relative to an inner surface of the substrate support 108, which may result in an elevated portion relative to the inner surface. This can improve thermal control of the substrate 112 by the substrate support 108. As noted above, the substrate support 108 can serve as a heater, whether through absorption of externally supplied radiant or energy, or internal heating through resistive or convective heating.

The substrate support 108 can have a variety of dimensions. The substrate support 108 can have a thickness of between about 1 mm and 15 mm and in some embodiments is about 3.8 mm. A diameter of the substrate support 108 (along the horizontal axis 132) may be between about 100 mm and 500 mm and in some embodiments is configured to support 300-mm wafers. The diameter of the substrate support 108 may be smaller than an inner diameter of the portion of the arc formed by the gas delivery apparatus 136. In this way, the substrate support 108 may freely move between the upper position 120 and the lower position 124 without coming in contact with the gas delivery apparatus 136.

FIG. 2 shows a perspective view of an example reactant vapor delivery system 200. The reactant vapor delivery system 200 may be included within a reaction chamber in some embodiments. The reactant vapor delivery system 200 includes a gas delivery apparatus 236 and a substrate support 208 that is controlled by a shaft 244. The gas delivery apparatus 236 can include one or more apertures 240. The gas delivery apparatus 236 may be supported by one or more apparatus supports 256. Only one apparatus support 256 is shown, but two or more are possible. The apparatus support 256 may be coupled to a wall of the reaction chamber and may support the gas delivery apparatus 236 using a hook or some other support structure. As shown, the gas delivery apparatus 236 can have a curved or arc portion. The arc portion may generally track or parallel a curvature of the edge of the substrate support 208. As shown, the substrate support 208 may be symmetrical about the vertical axis 228.

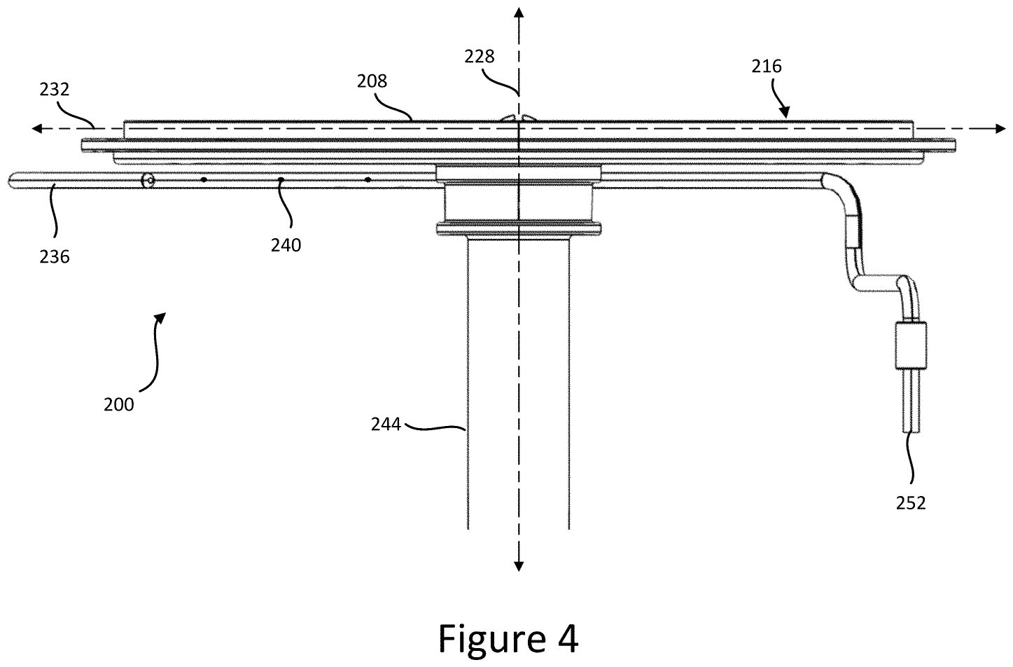

As shown the gas delivery apparatus 236 has a greater radial dimension than the substrate support 208. For example, the gas delivery apparatus 236 shown has a greater arc diameter than the substrate support 208. This can allow the substrate support 208 to be raised above (in the upper position, not shown) and lowered below (in the lower position, not shown) the gas delivery apparatus 236, as needed, by the shaft 244. The arc portion of the gas delivery apparatus 236 may be substantially coplanar with the top side 216 of the substrate support 208 in certain positions of the substrate support 208, although as shown the gas delivery apparatus 236 is disposed slightly below the top side 216 of the substrate support 208 (see FIG. 4).

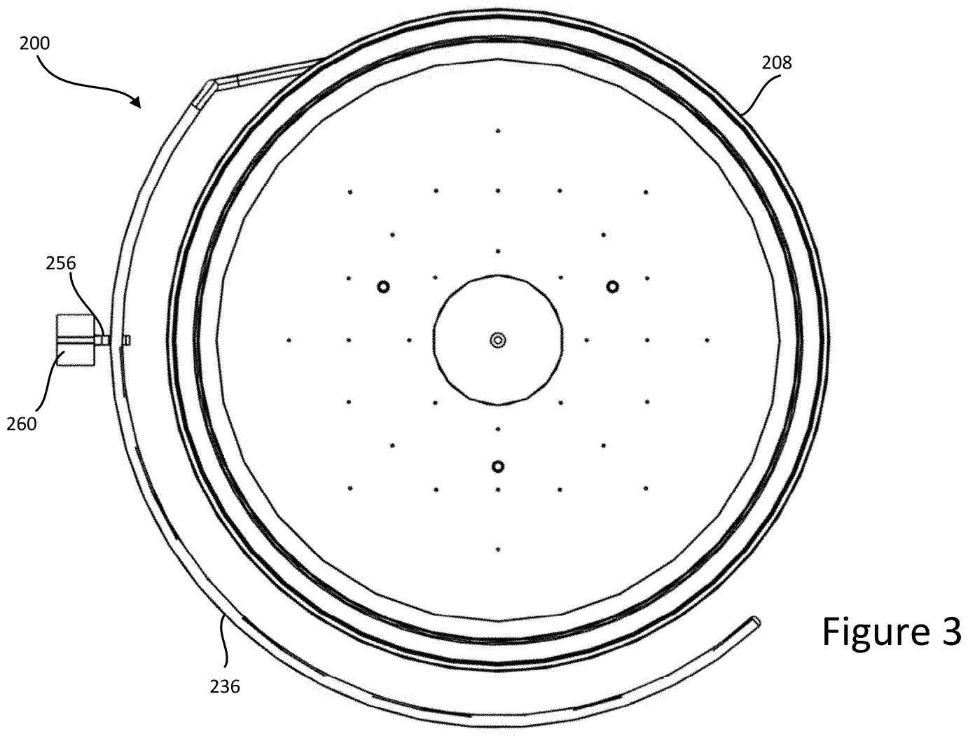

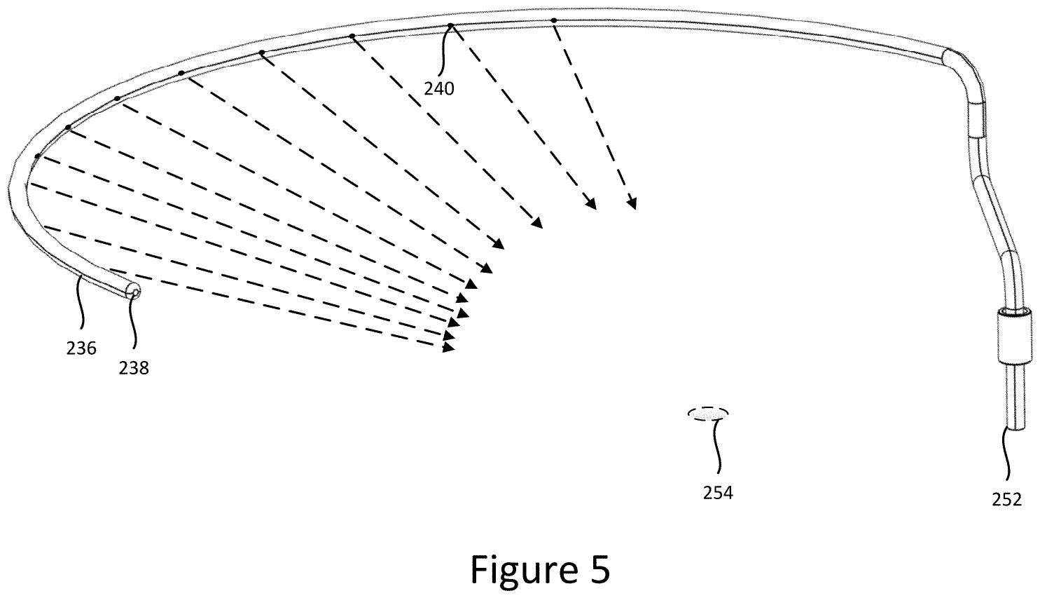

FIG. 3 shows a top view of the example reactant vapor delivery system 200 of FIG. 2. As shown, the arc portion of the gas delivery apparatus 236 is approximately 170°, but other radial dimensions of the arc portion are possible. FIG. 4 shows a side view of the example reactant vapor delivery system 200 of FIG. 2. Some of the apertures 240 of the gas delivery apparatus 236 can be seen in FIG. 4. An inlet 252 of the gas delivery apparatus 236 is shown. The inlet 252 may be configured to couple to a base (see FIG. 6C and attendant description) of the reaction chamber. In some embodiments, the inlet 252 may have a substantially similar diameter as a terminus 238 (FIG. 5, opposite end of the inlet 252) of the gas delivery apparatus 236. The terminus 238 may include a venting aperture, which can be configured to prevent any chemistry trapping within the terminus 238 during processes, thus reducing the risk of chemical contamination within the gas delivery apparatus 236 and/or within the reaction chamber. In some embodiments, the terminus 238 is closed.

FIG. 5 shows the gas delivery apparatus 236 of FIG. 2. The gas delivery apparatus 236 includes an elongate tube that is configured to be disposed within the reaction chamber (not shown). The tube is substantially hollow and allows gas to pass from a gas source (not shown) of the reactor, through the inlet 252, and to the apertures 240 via an interior of the tube. As shown, the elongate tube includes a plurality of straight and curved portions. For example, the tube may be configured to be straight starting at the inlet 252 and include one or more downstream curved portions. One or more of the plurality of straight portions may be substantially vertical, which may help support the rest of the gas delivery apparatus 236. The elongate tube may have a substantially equal diameter throughout the gas delivery apparatus 236, although other arrangements are possible.

The tube may have an outer diameter and an inner diameter. The outer diameter may be about 2 mm, about 3 mm, about 4 mm, about 5 mm, about 6 mm, about 7 mm, about 8 mm, about 9 mm, about 10 mm, about 12 mm, or fall within any range having any of the above values as endpoints. The selection of the outer diameter may be constrained by the size of the reaction chamber, the volume and/or velocity of desired gas flow. In some embodiments, the outer diameter is about 6.4 mm. The inner diameter (which defines an interior of the tube through which gas can flow) may be about 0.3 mm, about 0.5 mm, about 0.8 mm, about 1 mm, about 2 mm, about 3 mm, about 5 mm, or fall within any range having any of the above values as endpoints. The selection of the inner diameter may be constrained by the volume and/or velocity of gas flow required and/or the type of material of the gas delivery apparatus 236. The gas delivery apparatus 236 may be made of a substantially rigid material, such as aluminum metal (e.g., Al 6061/6063) or some other elemental metal or metal alloy. In some embodiments, the material is configured to be anti-corrosive against oxidizing chemicals, such as nitrogen trifluoride (NF₃) or other reactive chemicals.

In the illustrated embodiment of FIG. 5, each of the one or more apertures 240 is configured to direct gas toward a chamber outlet 254 (schematically shown with the dotted oval), as indicated by the dotted arrows. The direction of the released gas depends upon both the relative position of the lower chamber outlet 254 and can be in part downward as shown, or upward, if the chamber outlet 154 is above the gas delivery apparatus 236. Additionally or alternatively, each of the apertures 240 can be positioned around the arc portion of the elongate tube (e.g., within an interior portion of the arc portion of the tube) such that the general direction of the gas is at least generally toward the chamber outlet 254. The positioning of the gas delivery apparatus 236 relative to the lower chamber outlet 254, the substrate support (see FIGS. 1-4) and other reactor equipment can help accelerate processing using the gas delivery apparatus 236 (e.g., speed up cleaning processes), which can reduce downtime of the reaction chamber (e.g., during cleaning procedures) and/or reduce time between deposition or other reaction processes.

Each aperture 240 may have a diameter of about 0.2 mm, about 0.5 mm, about 0.7 mm, about 1 mm, about 1.5 mm, about 2 mm, about 2.5 mm, or fall within any range having any of the above values as endpoints. The diameter of each aperture 240 of the gas delivery apparatus 236 may be based at least in part on the desired flow rate of the gas system and/or on the size of the substrate needed to be processed.

The arc portion of the gas delivery apparatus 236 can have an outer diameter of about 250 mm, about 300 mm, about 350 mm, about 400 mm, about 450 mm, about 500 mm, about 550 mm, any value therein, or fall within any range having any values therein as endpoints. The outer diameter of the arc portion of the gas delivery apparatus 236 may be based at least in part on the outer dimension (e.g., outer diameter) of the substrate support 208. Otherwise, the range of positions of the substrate support 208 may be reduced without colliding the substrate support 208 with the gas delivery apparatus 236. In some embodiments, the outer diameter of the arc portion of the gas delivery apparatus 236 is between about 400 mm and 430 mm, for example about 416 mm, where the substrate support is configured to support 300-mm wafers.

In some embodiments, the gas may be heated prior to delivery to the gas delivery apparatus 236. This may be accomplished in one or more ways. In some embodiments, a heater jacket is disposed about tubing that delivers reactant vapors to the inlet 252 of the gas delivery apparatus 236. The heating element(s) may be configured to keep the temperature of the gas within a given portion of the gas delivery apparatus 236 to within a specific temperature range and/or above a minimum temperature. For example, the heating element(s) (e.g., heating jacket) may be configured to maintain a target or average temperature of gas flowing through the inlet 252 at about 70° C., at about 90° C., at about 110° C., at about 130° C., at about 150° C., at about 170° C., at about 200° C., at about 225° C., or fall within any range having any of the above values as endpoints.

Preheating the vapors provided through the gas delivery apparatus can advantageously alleviate or prevent convective cooling of equipment within the reaction chamber cooling and attendant interference with temperature control within the chamber, which could in turn cause variability in substrate processing and or cleaning reactions between substrates.

FIGS. 6A-6C show an example inlet adapter 600 that may be used to couple an elongate gas delivery apparatus (e.g., the gas delivery apparatus 136, the gas delivery apparatus 236) to a base of a chamber. FIG. 6A is a perspective view of the inlet adapter 600, and FIG. 6B is a cross-sectional side view of the inlet adapter 600. The inlet adapter 600 can include an adapter head 604, an adapter nut 608, and an adapter bolt 612. The adapter head 604 may include one or more recesses 616. In some embodiments, the recess 616 may be configured to receive an O-ring or other sealing element. A top side of the adapter head 604 can be configured to couple and seal to the base of the chamber. The delivery apparatus adapter 600 can be hollow to allow flow of vapor therethrough.

Advantageously, the inlet adapter 600 can allow for improved access to the elongate delivery apparatus. For example, the inlet adapter 600 may allow for ready installation or retrofitting with the chamber. In some embodiments, the inlet adapter 600 can include an adapter nut 608 and a bolt insert 620 configured to be removably coupled to an interior of the adapter nut 608. In some embodiments, the adapter nut 608 and bolt insert 620 are adhered (e.g., welded) together for more secure coupling. FIG. 6C shows the inlet adapter 600 coupled to the inlet 252 of the gas delivery apparatus 236 and to the chamber base 248. As shown, an O-ring 624 is disposed between the adapter head 604 and the base of the chamber base 248.

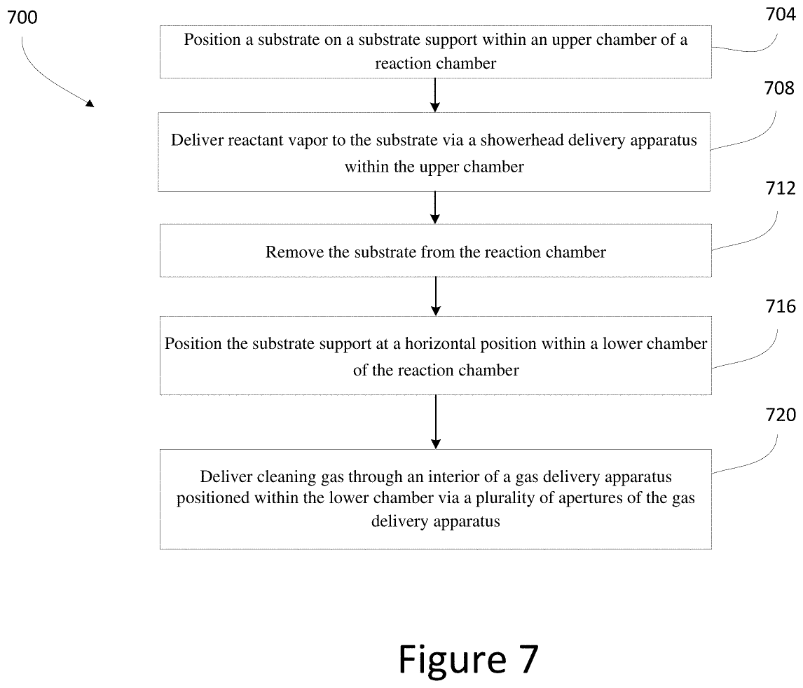

FIG. 7 shows an example method 700 that may be performed by one or more systems described above (e.g., the reactant vapor delivery system 100, the reactant vapor delivery system 200), and particularly by the controller for the system. At block 704 a substrate is positioned on a substrate support within an upper, or processing, position (see, e.g., 120 in FIG. 1) of a reaction chamber of a reactor. Reaction vapors can be delivered through a primary gas delivery apparatus, such as the showerhead 138 of FIG. 1, at block 708. In one embodiment, the substrate processing can comprise vapor deposition, such as chemical vapor deposition (CVD), of a metallic material on the substrate.

Subsequently, at block 712, the substrate can be removed from the reaction chamber of the reactor, and at block 716 the system can position the substrate support (e.g., substrate support 108 or 208) at a horizontal position within a lower chamber (e.g., lower chamber 168) within the reactor. In the lower chamber, a top of the substrate support may be below a plurality of apertures (e.g., apertures 140, apertures 240) of a gas delivery apparatus (e.g., delivery apparatus 136, delivery apparatus 236). The gas delivery apparatus can have an inner radial dimension greater than an outer radial dimension of the substrate support. For example, the gas delivery apparatus may have an inner diameter greater than an outer diameter of the substrate support. At block 720 the system can pass gas (e.g., cleaning gas) through an interior of the gas delivery apparatus positioned within the lower chamber via the plurality of apertures while the substrate support is in the lower chamber. This may allow gas to come in contact with a top side of the substrate support (e.g., to clean the substrate support), with a top side of a substrate (e.g., to delivery chemical thereon), and/or to elements in an upper portion of the reactor (e.g., to clean those elements). The gas may be cleaning gas configured to clean residue left on surfaces of the reaction chamber by the substrate processing. In the example herein of metallic material deposition, and particularly molybdenum deposition, the cleaning gas supplied through the gas delivery apparatus can comprise a halide gas. In a particular example, the cleaning gas comprises NF₃.

Additionally or alternatively, the system can actuate the substrate support to an upper position along a vertical axis within the reactor. In the upper position a top of the substrate support may be above the plurality of apertures. The system may pass reactant vapors, such as cleaning gas, through an interior of the delivery apparatus and into the reactor via the plurality of apertures while the substrate support is in the upper position. This may allow cleaning gas to come in contact with an underside of the substrate support (e.g., to clean the substrate support) and other equipment surfaces within a lower portion of the reactor. Passing the reactant vapors through an interior of the delivery apparatus and into the reactor may include directing the gas from each of the plurality of apertures toward a chamber outlet (e.g., lower chamber outlet 154, lower chamber outlet 254) within the reactor. Additional features of one or more aspects of the method 600 can include functionality and features of the reactant vapor delivery system 100 and/or the reactant vapor delivery system 200 disclosed above with respect to FIGS. 1-5.

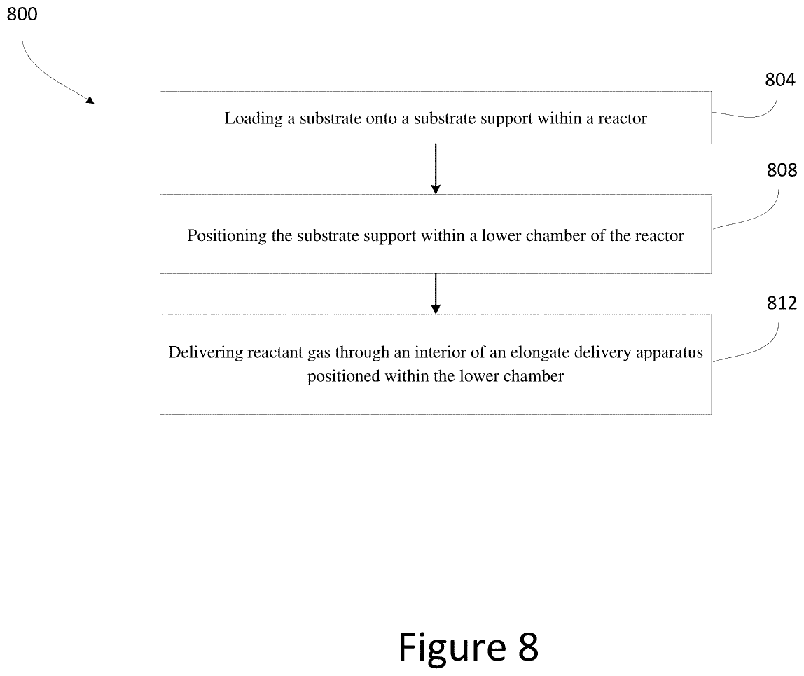

FIG. 8 shows an example method 800 that may be performed by one or more systems described above (e.g., the reactant vapor delivery system 100, the reactant vapor delivery system 200). The gas delivery apparatus may include a plurality of apertures in fluid communication with an interior of the gas delivery apparatus. Initially, at block 804, a substrate may be loaded onto the substrate support within the reaction chamber of a reactor, and at block 808 the support can be positioned for processing within a lower chamber of the reaction chamber. The processing position may be the upper position 120 of FIG. 1, or may be position with the gas delivery apparatus level with the edge of the substrate support or the lower position 124 of FIG. 1, either of which allows access of gas through the gas delivery apparatus to the substrate surface. The showerhead delivery apparatus may be disposed above a substrate support and configured to delivery vapor to the substrate thereon. The elongate delivery apparatus can have an inner radial dimension greater than an outer radial dimension of the substrate support. At block 812, process reactant vapors can be delivered through the gas delivery apparatus and into the reaction chamber via the plurality of apertures. Process gas can also be delivered through the showerhead delivery apparatus. In one embodiment, the same process reactant vapors are provided through both showerhead and the lower gas distribution apparatus. In another embodiment, one reactant is supplied through the showerhead, and a different reactant is supplied through the lower gas distribution apparatus. Employing both the vertical flow from the showerhead and cross-flow from the gas distribution apparatus can advantageously allow tuning of gas flows (mass transport) for uniformity that would not be available with reactant vapors through the showerhead alone.

In other embodiments, process reactant vapors can be supplied through the lower gas distribution apparatus only, preferably with the substrate support in a lower position. In still other embodiments, reactant vapors are supplied through the gas distribution apparatus during substrate processing (e.g., vapor deposition of metallic material), the substrate is removed from the chamber, the gas distribution apparatus is purged of reactant vapors, and cleaning gas (e.g., NF₃) is supplied through the lower chamber gas distribution apparatus with the substrate support in a lower position (below or level with the gas distribution apparatus) Accordingly, the partial ring in the lower chamber provides additional flexibility for use during primary processing with the showerhead, in separate processing using cross-flow only, in combinations for sequential in situ processing, and/or equipment cleaning steps between substrate processing steps.

### ILLUSTRATIVE EXAMPLES

Various examples are provided below.

In a 1st example, a reactor comprising: a flange disposed between an upper chamber and a lower chamber; a substrate support configured to support a substrate on a top side of the substrate support, the substrate support additionally configured to be vertically actuated between an upper position and a lower position within the reaction chamber; a primary gas delivery apparatus disposed within the upper chamber and configured to deliver gas to an upper surface of the substrate; and an elongate gas delivery apparatus disposed within the lower chamber and configured to partially surround the substrate support, the delivery apparatus configured to allow gas to pass through an interior thereof and out a plurality of apertures in fluid communication with the interior of the delivery apparatus.

In a 2nd example, a reactor comprising: a reaction chamber; a substrate support at a horizontal position within the reaction chamber, the substrate support configured to support a substrate on a top side of the substrate support, the substrate support additionally configured to be vertically actuated between an upper position and a lower position within the reaction chamber; an elongate gas delivery apparatus disposed within the reaction chamber to partially surround the substrate support horizontal position, the gas delivery apparatus having an inner horizontal width greater than a horizontal width of the substrate support, the delivery apparatus configured to allow gas to pass through an interior thereof, the delivery apparatus comprising a plurality of apertures in fluid communication with the interior of the delivery apparatus, each of the plurality of apertures configured to allow passage of the gas from the interior of the delivery apparatus into the reaction chamber; wherein the plurality of apertures are disposed: below the top of the substrate support when the substrate support is in the upper position; and level with or above an edge of the substrate support when the substrate support is in the lower position.

In a 3rd example, the reactor of example 2, wherein the reaction chamber comprises a chamber outlet configured to draw the gas out of the chamber.

In a 4th example, the reactor of example 3, wherein the delivery apparatus comprises an arched segment.

In a 5th example, the reactor of example 4, wherein the arched segment encompasses an angle of between about 180° and about 270°.

In a 6th example, the reactor of any of examples 4-5, wherein each of the plurality of apertures are disposed along the arched segment.

In a 7th example, the reactor of example 6, wherein each of the plurality of apertures is configured to direct the gas toward the chamber outlet.

In an 8th example, the reactor of any of examples 4-7, wherein each of the plurality of apertures are disposed along an inner radius of the arched segment.

In a 9th example, the reactor of any of examples 2-8, wherein an inlet of the delivery apparatus is configured to couple to a base of the reaction chamber.

In a 10th example, the reactor of any of examples 2-9, wherein each of the plurality of apertures are configured to be disposed substantially within a plane orthogonal to a vertical axis.

In an 11th example, the reactor of any of examples 2-10, further comprising a flange disposed between an upper chamber and a lower chamber of the reactor.

In a 12th example, the reactor of example 11, wherein, in the upper position, the substrate support is configured to form a seal with the flange.

In a 13th example, the reactor of any of examples 11-12, further comprising a primary gas delivery mechanism disposed within the upper chamber and configured to deliver gas downward toward a top of the substrate.

In a 14th example, a delivery apparatus for delivering gas within a reaction chamber, the delivery apparatus comprising: an elongate tube configured to be disposed within the reaction chamber, the tube configured to allow gas to pass through an interior thereof, the tube comprising an arched segment partially surrounding a horizontal position of a substrate support within the chamber; an inlet adapter configured to couple to a base of the reaction chamber and feed reaction vapors therethrough to the tube; and a plurality of apertures in fluid communication with the interior of the tube, each of the plurality of apertures configured to allow passage of the gas from the interior of the delivery apparatus into the reaction chamber.

In a 15th example, the delivery apparatus of example 14, wherein the tube is configured to be disposed substantially within a plane orthogonal to a vertical axis along which the substrate support is configured to be actuated between an upper position and a lower position within the reaction chamber.

In a 16th example, the delivery apparatus of example 15, wherein the tube is disposed such that the plurality of apertures are: below the top of the substrate when the substrate support is in the upper position; and above the top of the substrate when the substrate support is in the lower position.

In a 17th example, the delivery apparatus of any of examples 14-16, wherein the delivery apparatus comprises an arched segment.

In a 18th example, the delivery apparatus of example 17, wherein the arched segment encompasses an angle of between about 120° and about 270°.

In a 19th example, the delivery apparatus of any of examples 17-18, wherein each of the plurality of apertures are disposed along the arched segment.

In a 20th example, the delivery apparatus of example 19, wherein each of the plurality of apertures is configured to direct the gas toward a chamber outlet within the reaction chamber.

In a 21st example, the delivery apparatus of any of examples 19-20, wherein each of the plurality of apertures are disposed along an inner radius of the arched segment.

In a 22nd example, a method for delivering cleaning gas within a reactor, the method comprising: positioning a substrate on a substrate support within an upper chamber of a reactor; delivering reactant vapor to the substrate via a showerhead delivery apparatus within the upper chamber; removing the substrate from the reactor; positioning the substrate support at a horizontal position within a lower chamber of the reactor; and delivering cleaning gas through an interior of a gas delivery apparatus positioned within the lower chamber via a plurality of apertures of the gas delivery apparatus.

In a 23rd example, the method of example 22, wherein delivering cleaning gas through the interior of the gas delivery apparatus comprises delivering cleaning gas through the interior of an arcuate tube within the lower chamber.

In a 24th example, the method of example 23, wherein the arcuate tube subtends an arc of between about 90° and about 270°.

In a 25th example, a method for delivering reactant vapor within a reactor, the method comprising: loading a substrate onto a substrate support within a reactor; positioning the substrate support within a lower chamber of the reactor; and delivering reactant gas through an interior of an elongate delivery apparatus positioned within the lower chamber.

In a 26th example, the method of example 25, wherein delivering reactant gas through the interior of the elongate delivery apparatus comprises delivering reactant gas through the interior of an arcuate tube within the lower chamber.

In a 27th example, the method of example 26, wherein the arcuate tube subtends an arc of between about 90° and about 180°.

In a 28th example, the method of example 27, further comprising:

evacuating the reactant gas through a chamber outlet generally opposite the arc subtended by the arcuate tube.

In a 29th example, the method of any of examples 27-28, further comprising:

delivering reactant vapor to the substrate via a showerhead delivery apparatus within the upper chamber.

In a 30th example, the method of example 29, wherein delivering the reactant vapor to the substrate via the showerhead delivery apparatus within the upper chamber is simultaneous with delivering the reactant gas through the interior of the elongate delivery apparatus positioned within the lower chamber.

In a 31st example, a method for delivering chamber gas within a reaction chamber, the method comprising: actuating a substrate support between a processing position for processing a substrate and a lower position along a vertical axis within the reaction chamber, wherein, in the lower position, a top of the substrate support is level with or below an arcuate delivery apparatus, wherein the arcuate delivery apparatus has an inner width greater than an outer width of the substrate support; and while in the lower position, passing gas through an interior of the arcuate delivery apparatus and into the reaction chamber via a plurality of apertures of the arcuate delivery apparatus.

In a 32nd example, the method of example 31, further comprising: actuating a substrate support to an upper position along the vertical axis within the reaction chamber, wherein in the upper position a top of the substrate support is above the plurality of apertures; and while the substrate support is in the upper position, passing the gas through the interior of the delivery apparatus and into the reaction chamber via the plurality of apertures.

In a 33rd example, the method of any of examples 31-32, wherein passing the gas through an interior of the delivery apparatus and into the reaction chamber comprises directing, from each of the plurality of apertures, the gas toward a chamber outlet within the reaction chamber.

The present aspects and implementations may be described in terms of functional block components and various processing steps. Such functional blocks may be realized by any number of hardware or software components configured to perform the specified functions and achieve the various results. For example, the present aspects may employ various sensors, detectors, flow control devices, heaters, and the like, which may carry out a variety of functions. In addition, the present aspects and implementations may be practiced in conjunction with any number of processing methods, and the apparatus and systems described may employ any number of processing methods, and the apparatus and systems described are merely examples of applications of the invention.

What is claimed is:

1. A reactor comprising:
a flange disposed between an upper chamber and a lower chamber;
a substrate support configured to support a substrate on a top side of the substrate support, the substrate support additionally configured to be vertically actuated between an upper position and a lower position within the reaction chamber;
a primary gas delivery apparatus disposed within the upper chamber and configured to deliver gas to an upper surface of the substrate; and
an elongate gas delivery apparatus disposed within the lower chamber and configured to partially surround the substrate support, the delivery apparatus configured to allow gas to pass through an interior thereof and out a plurality of apertures in fluid communication with the interior of the delivery apparatus.

2. A reactor comprising:
a reaction chamber;
a substrate support at a horizontal position within the reaction chamber, the substrate support configured to support a substrate on a top side of the substrate support, the substrate support additionally configured to be vertically actuated between an upper position and a lower position within the reaction chamber;
an elongate gas delivery apparatus disposed within the reaction chamber to partially surround the substrate support horizontal position, the gas delivery apparatus having an inner horizontal width greater than a horizontal width of the substrate support, the delivery apparatus configured to allow gas to pass through an interior thereof, the delivery apparatus comprising a plurality of apertures in fluid communication with the interior of the delivery apparatus, each of the plurality of apertures configured to allow passage of the gas from the interior of the delivery apparatus into the reaction chamber;
wherein the plurality of apertures are disposed:
below the top of the substrate support when the substrate support is in the upper position; and
level with or above an edge of the substrate support when the substrate support is in the lower position.

3. The reactor of claim 2, wherein the reaction chamber comprises a chamber outlet configured to draw the gas out of the chamber.

4. The reactor of claim 3, wherein the delivery apparatus comprises an arched segment.

5. The reactor of claim 4, wherein the arched segment encompasses an angle of between about 180° and about 270°.

6. The reactor of claim 4, wherein each of the plurality of apertures are disposed along the arched segment.

7. The reactor of claim 6, wherein each of the plurality of apertures is configured to direct the gas toward the chamber outlet.

8. The reactor of claim 4, wherein each of the plurality of apertures are disposed along an inner radius of the arched segment.

9. The reactor of claim 2, wherein an inlet of the delivery apparatus is configured to couple to a base of the reaction chamber.

10. The reactor of claim 2, wherein each of the plurality of apertures are configured to be disposed substantially within a plane orthogonal to a vertical axis.

11. The reactor of claim 2, further comprising a flange disposed between an upper chamber and a lower chamber of the reactor.

12. The reactor of claim 11, wherein, in the upper position, the substrate support is configured to form a seal with the flange.

13. The reactor of claim 11, further comprising a primary gas delivery mechanism disposed within the upper chamber and configured to deliver gas downward toward a top of the substrate.

14. A delivery apparatus for delivering gas within a reaction chamber, the delivery apparatus comprising:
an elongate tube configured to be disposed within the reaction chamber, the tube configured to allow gas to pass through an interior thereof, the tube comprising an arched segment partially surrounding a horizontal position of a substrate support within the chamber;
an inlet adapter configured to couple to a base of the reaction chamber and feed reaction vapors therethrough to the tube; and
a plurality of apertures in fluid communication with the interior of the tube, each of the plurality of apertures configured to allow passage of the gas from the interior of the delivery apparatus into the reaction chamber.

15. The delivery apparatus of claim 14, wherein the tube is configured to be disposed substantially within a plane orthogonal to a vertical axis along which the substrate support is configured to be actuated between an upper position and a lower position within the reaction chamber.

16. The delivery apparatus of claim 15, wherein the tube is disposed such that the plurality of apertures are:
below the top of the substrate when the substrate support is in the upper position; and
above the top of the substrate when the substrate support is in the lower position.

17. The delivery apparatus of claim 14, wherein the delivery apparatus comprises an arched segment.

18. The delivery apparatus of claim 17, wherein the arched segment encompasses an angle of between about 120° and about 270°.

19. The delivery apparatus of claim 17, wherein each of the plurality of apertures are disposed along the arched segment.

20. The delivery apparatus of claim 19, wherein each of the plurality of apertures are disposed along an inner radius of the arched segment.
